(19) United States
(12) Patent Application Publication
(10) Pub. No.: US 2009/0032825 A1
(43) Pub. Date: Feb. 5, 2009

(54) Structure Of LED-Based Display Module And Method For Manufacturing The Same

(76) Inventors: Yun-Chiang Mo, Hsinchu (TW); Yu-Chun Lin, Hsinchu (TW); Hsiao-Yi Cheng, Hsinchu (TW); Chia-Hua Liao, Hsinchu (TW); Ching-Ping Liu, Hsinchu (TW)

Correspondence Address: LIN & ASSOCIATES INTELLECTUAL PROPERTY, INC., P.O. BOX 2339, SARATOGA, CA, 95070-0339, US

(21) Appl. No.: 11/832,654

(22) Filed: Aug. 2, 2007

(51) Int. Cl. H01L 33/00; H01L 21/00

(52) U.S. Cl. 257/88; 438/28; 257/E33.001

(57) ABSTRACT

The display module contains a circuit board, a heat-resistant and transparent protective layer, and a transparent and waterproofing enclosing member. The circuit board has a number of LED devices configured on the front surface and at least a terminal on the back surface. The LED devices are electrically and signally wired to the terminal so that electricity and video signals are fed to the LED devices via the terminal. The protective layer is coated on the outer surfaces of the LED devices and the circuit board so as to protect the wiring, the soldering contacts, and the electrical components of the circuit board from being damaged by the high temperature during the process of forming the enclosing member. The enclosing member wraps the circuit board and the LED devices entirely within and exposes only the terminal.

### BACKGROUND OF THE INVENTION

1. Field of the Invention

The present invention generally relates to large-scaled, LED (light emitting diode) based display modules, and more particularly to a structure of such a display module and a manufacturing method thereof for superior waterproofing.

2. The Prior Arts

Due to the recent advancement of LED technologies, large-scaled display panels using LEDs are now commonly found in places such as stadiums, arenas, plazas, train stations, and airport terminals for the video display of news, sports events, commercial advertisements, etc. controlled by built-in computers. These large-scaled display panels are usually pieced together by an array of display modules, each controlled by the computer to show a section of the video images where, taken together, complete images are presented. As these display panels are installed outdoor, they have to be highly watertight or waterproof.

FIGS. 1A and 1B are exploded and assembled sectional views of a conventional large-scaled LED display module. As illustrated, the display module contains a front cover 11, a circuit board 12 having an array of LEDs 121 on the front surface, a support frame 13, and a waterproof pad 14 sequentially arranged in this order from outside towards inside. The front surface of the circuit board 12 is coated with a layer of waterproof adhesive (not shown), together with that the circuit board 12 is sandwiched between the front cover 11 and the support frame 13, so as to achieve waterproofing. The front cover 11 has a number of through openings 111 so that the LEDs 121 are exposed to the front (as shown in FIG. 1B). The waterproof pad 14 is affixed to the back surface of the frame 13 so as to prevent water from permeating to the circuit board 12 when the frame 13 is installed on a structure for supporting the entire display panel.

As can be understood from the foregoing description, the conventional large-scaled, LED-based display module achieves waterproofing mainly through the tightness and closeness in the assembly of its structural components. This implies that each display module has to be assembled with great care and, therefore, the installation of the entire display panel is rather time consuming and labor intensive.

### SUMMARY OF THE INVENTION

Accordingly, a major objective of the present invention is to provide a structure of and a method for manufacturing a large-scaled, LED-based display module that has superior waterproofing. To achieve this objective, the circuit board and the LED devices of the display module are completely wrapped inside a waterproofing transparent member.

Another major objective of the present invention is to provide a structure of and a method for manufacturing a large-scaled, LED-based display module that does not completely block the view from behind the display module. To achieve this objective, a number of through openings are pre-arranged in the circuit board and these openings offer improved viewing to people behind the display module.

Yet another objective of the present invention is to provide a structure of and a method for manufacturing a large-scaled, LED-based display module that is very easy to install. To achieve this objective, the LED devices and the circuit board of the display module are completely wrapped inside a waterproofing transparent member so that the display module can be installed as an integral piece without worrying the closeness and tightness among its components. In addition, as a result, the circuit board and the LED devices could be more flexibly designed and arranged without worrying their implication to the waterproofing quality of the display module.

Still another objective of the present invention is to provide a structure of and a method for manufacturing a large-scaled, LED-based display module that is high-quality, low-cost, and robust. To achieve this objective, the LED devices and the circuit board of the display module are completely wrapped inside a waterproofing transparent member so that the components are well protected and, as fewer components are used and less effort is required for joining these components together, the overall manufacturing cost is reduced.

The manufacturing method provided by the present invention is as follows. First, the circuit board is provided, with the LED devices configured on the front surface and at least a terminal on the back surface with appropriate electrical and signal wiring therebetween. Then, a heat-resistant and transparent protective layer is coated completely on the surfaces of the LED devices and the circuit board. And, finally, the LED devices and the circuit board are completely wrapped in a transparent and waterproofing enclosing member and only the terminal is exposed for feeding electricity and video signals to the display module.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIGS. 1A and 1B are exploded and assembled sectional views of a conventional large-scaled LED display module.

FIG. 2 is a flow chart showing the processing steps of forming a display module according to the present invention.

FIG. 3 is a sectional view showing a large-scaled, LED-based display module according to a first embodiment of the present invention.

FIG. 4 is a front view showing the large-scaled, LED-based display module of FIG. 3.

FIG. 5 is a front view showing a large-scaled, LED-based display module according to a second embodiment of the present invention.

FIG. 6 is a front view showing a large-scaled, LED-based display module according to a third embodiment of the present invention.

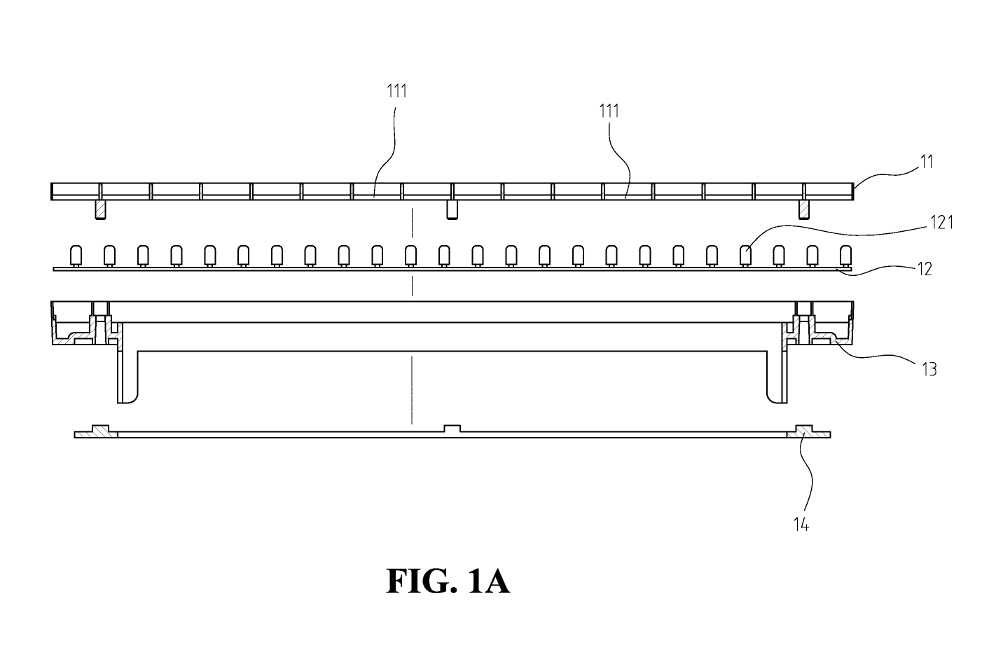

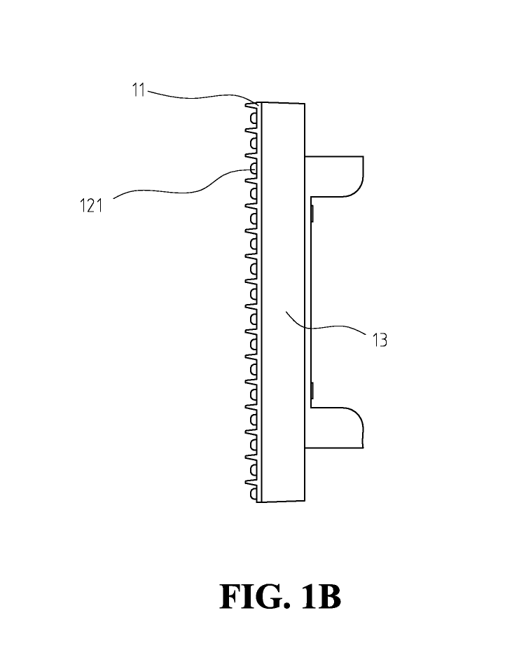

### DETAILED DESCRIPTION OF THE PREFERRED EMBODIMENT

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

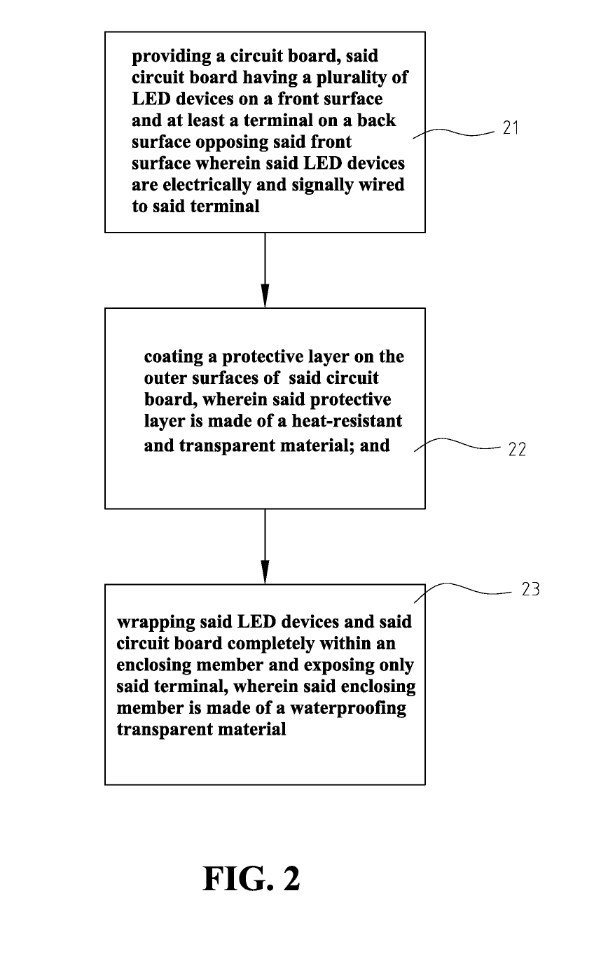

FIG. 2 shows the steps of the manufacturing method of the present invention. As illustrated, in the step 21, a circuit board having a number of LED devices as light source on the front surface and at least a terminal on the back surface is provided. The LED devices are electrically and signally wired to the terminal so that external power and video signals can be fed to the LED devices via the terminal. In the step 22, a protective layer is coated completely on the surfaces of the LED devices and the circuit board. The protective layer is made of a heat-resistant and transparent material. Then, in the step 23, the LED devices and the circuit board are completely wrapped inside an enclosing member for waterproofing and only the terminal is exposed from the enclosing member. The enclosing member is made of a transparent material so as not to block the light from the LED devices. The protective member formed in the step 22 is for the protection of the LED devices, the wiring, the soldering contacts and other electrical components on the circuit board from being damaged by the high temperature during the process of forming the enclosing member in the step 23.

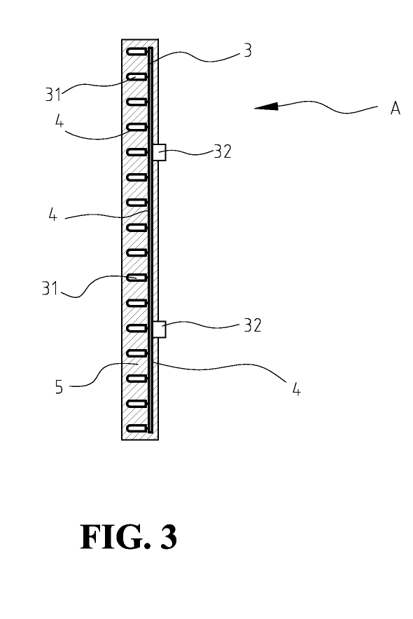

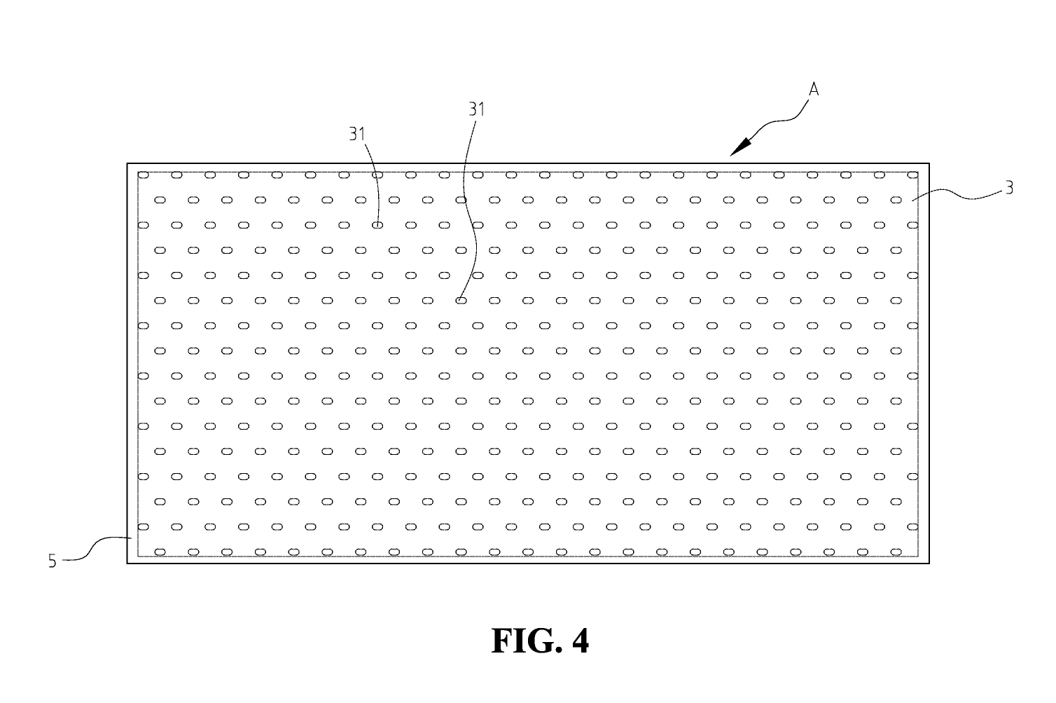

FIGS. 3 and 4 are sectional and front views of a large-scaled, LED-based display module A according to a first embodiment of the present invention. As illustrated, from the inside out, the display module A contains a circuit board 3, a protective layer 4, and an enclosing member 5. The circuit board 3 has a number of LED devices 31 configured on the front surface and at least a terminal 32 on the back surface. The LED devices 31 are electrically and signally wired to the terminal 32 so that electricity and video signals are fed to the LED devices 31 via the terminal 32. The terminal 32 could be a waterproof connector and could be electrically and signally connected to the terminals 32 of other display modules A. The circuit board 3 has other electrical components for power and signal distribution but, for simplicity, these components and the wirings are not shown in the drawings. As shown in FIG. 4, the LED devices 31 are arranged in an array with appropriate spacing therebetween. Each LED devices 31 is capable of producing red, green, and blue light and constitutes a pixel of the image displayed by the display module A (i.e., a section of an overall image displayed by the entire display panel). The protective layer 4 is a thin layer (shown the as thicker lines in the drawings) made of a transparent and heat-resistant material coated on the outer surfaces of the LED devices 31 and the circuit board 3. The purpose of the protective layer 4 is to protect the wiring, the soldering contacts, and the electrical components of the circuit board 3 and the LED devices 31 so that they won't get damaged by the high temperature during the process of forming the enclosing member 5. The enclosing member 5 is made of a transparent material such as a thermal-curable resin with good transparency and strength. One such material is the Methacrylic resin. The enclosing member 5 wraps the circuit board 3 and the LED devices 31 entirely within and exposes only the terminal 32.

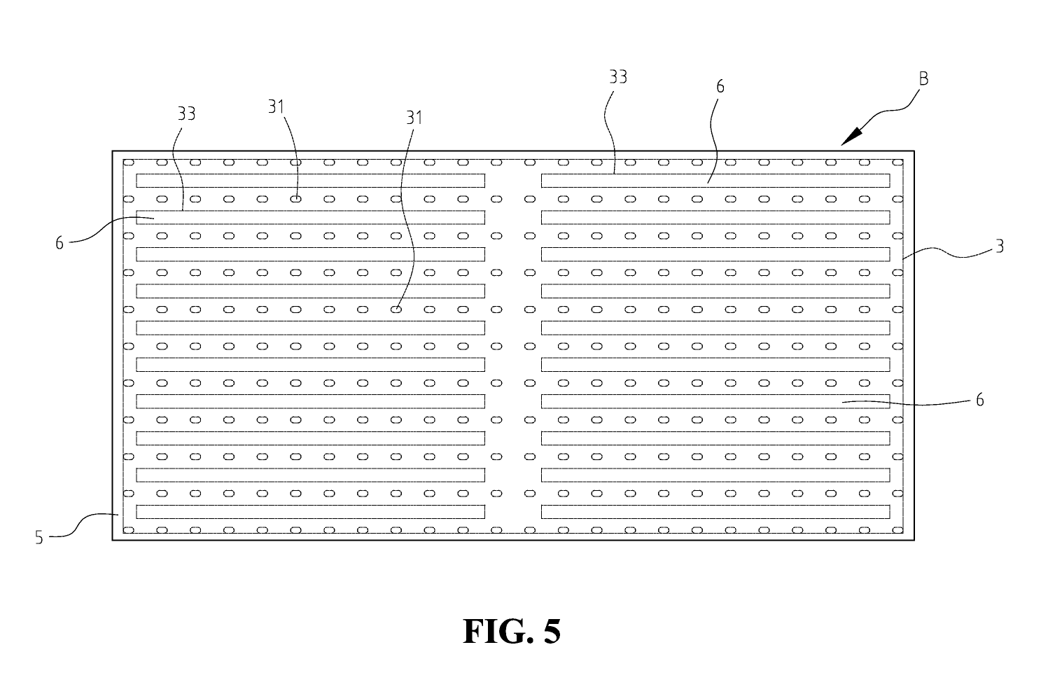

In the foregoing first embodiment, the circuit board 3 has a sizable opaque body that significantly blocks the view from behind. A second embodiment shown in FIG. 5, on the other hand, provides a remedy. As illustrated, the display module B is composed of and structured by components identical to those of the display module A. The difference lies in that the circuit board 3 of the display module B contains a number of pre-arranged through openings 33. In the present embodiment, the openings 33 have an elongated rectangular shape but the shape of the openings 33 is not necessarily limited as such. When the enclosing member 5 is formed, the openings 33 are also filled by the enclosing member 5. Since the enclosing member 5 is transparent, a number of transparent areas 6 are thereby formed in the display module B to offer a significant less blocking view from behind.

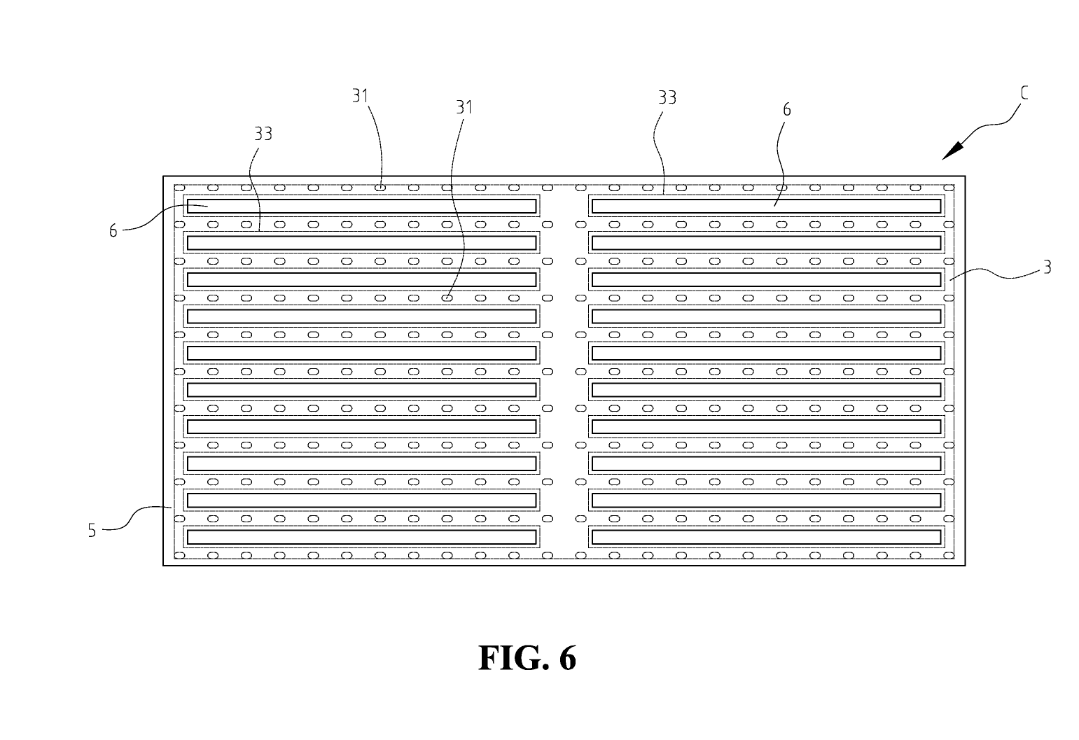

FIG. 6 provides a front view to a third embodiment of the present invention. As illustrated, the display module C is identical to the display module B. However, when the enclosing member 5 is formed in the present embodiment, the enclosing member 5 only covers the circumference of the openings 33 of the circuit board 3, instead of filling up the entire openings 33. As such, a number of through area 6 are formed in the display module C. Both the second and third embodiments of the present invention will not completely block the view from behind. When the display panel based on the second or third embodiment is installed on the outside of a building, the people inside the building therefore are able to enjoy a better view and also better daylight.

As described so fat, it should be clear that the display module according to the present invention is integrally formed into a single piece with the enclosing member providing superior waterproofing to the components inside. As such, the installation of the display modules and the display panel therefore can be conducted is significantly simplified without worrying the quality of waterproofing.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for manufacturing a LED-based display module, comprising the steps of:
providing a circuit board, said circuit board having a plurality of LED devices on a front surface and at least a terminal on a back surface opposing said front surface wherein said LED devices are electrically and signally wired to said terminal;
coating a protective layer on the outer surfaces of said circuit board, wherein said protective layer is made of a heat-resistant and transparent material; and
wrapping said LED devices and said circuit board completely within an enclosing member and exposing only said terminal, wherein said enclosing member is made of a waterproofing transparent material.

2. The method according to claim 1, wherein said enclosing member is made of thermal-curable resin.

3. The method according to claim 2, wherein said enclosing member is Methacrylic resin.

4. A LED-based display module, comprising:
a circuit board having a plurality of LED devices on a front surface and at least a terminal on a back surface opposing said front surface wherein said LED devices are electrically and signally wired to said terminal;
a protective layer coated on the outer surfaces of said LED devices and said circuit board, wherein said protective layer is made of a heat-resistant and transparent material; and
an enclosing member wrapping said LED devices and said circuit board completely within and exposing only said terminal, wherein said enclosing member is made of a waterproofing transparent material.

5. The display module according to claim 4, wherein said enclosing member is made of thermal-curable resin.

6. The display module according to claim 5, wherein said enclosing member is Methacrylic resin.

7. The display module according to claim 1, wherein said circuit board has a plurality of through openings.
